(19) United States
(12) Patent Application Publication
(10) Pub. No.: US 2020/0312734 A1
(43) Pub. Date: Oct. 1, 2020

(54) SEMICONDUCTOR PACKAGE WITH AN INTERNAL HEAT SINK AND METHOD FOR MANUFACTURING THE SAME

(71) Applicant: Powertech Technology Inc., Hukou Township (TW)

(72) Inventors: Ting-Feng Su, Hukou Township (TW); Chi-Liang Pan, Hukou Township (TW)

(73) Assignee: Powertech Technology Inc., Hukou Township (TW)

(21) Appl. No.: 16/363,036

(22) Filed: Mar. 25, 2019

(51) Int. Cl. H01L 23/367; H01L 23/28; H01L 23/498; H01L 23/00; H01L 21/56

(52) U.S. Cl. CPC H01L 23/367; H01L 23/28; H01L 23/49816; H01L 2021/60022; H01L 24/14; H01L 21/563; H01L 2225/06513; H01L 24/95

(57) ABSTRACT

A semiconductor package with an internal heat sink has a substrate, a chip and an encapsulation. The substrate has an embedded heat sink, a first wiring surface and a second wiring surface. The embedded heat sink has a first surface and a second surface. The second wiring surface of the substrate and the second surface of the heat sink are coplanar. The chip has an active surface and a rear surface mounted on the first surface of heat sink through a thermal interface material layer and the active surface is electrically connected to the first wiring surface of the substrate. The encapsulation is formed on the first wiring surface of the substrate and the encapsulation encapsulates the chip. The heat generated from the chip is quickly transmitted to the heat sink and dissipated to air through the heat sink. Therefore, a heat dissipation performance of the semiconductor package is increased.

### BACKGROUND OF THE INVENTION

### 1. Field of the Invention

The present invention is related to a semiconductor package, and more particularly to a semiconductor package with an internal heat sink and method for manufacturing the same.

### 2. Description of the Prior Arts

With reference to FIG. 5, a semiconductor package 50 has a chip 51 mounted on a BGA substrate 52, an encapsulation 53 encapsulating the chip 51 and an external heat sink 54 mounted on the encapsulation 53. Since the external heat sink 54 is mounted on the encapsulation 53, an operating heat generated from the chip 51 is dissipated to air through the external heat sink 54. Therefore, the thermal of the chip 51 may be kept in a normal range to maintain a normal operation when the chip 51 is operating.

Since a thermal conductivity of the encapsulation 53 is low, the external heat sink 54 mounted on the encapsulation 53 requires more time to dissipate the heat of the chip 51 to the normal range when a temperature of the chip 51 is rapidly increased. Therefore, a heat dissipation performance of the semiconductor package 50 having the external heat sink 54 is not good enough. To overcome the shortcomings of the semiconductor package, the present invention provides a semiconductor package with an internal heat sink to mitigate or obviate the aforementioned problems.

### SUMMARY OF THE INVENTION

An objective of the present invention is to provide a semiconductor package with an internal heat sink and method for manufacturing the same.

To achieve the objective as mentioned above, the semiconductor package has a substrate, a chip and an encapsulation. The substrate has a through hole, a heat sink mounted in the through hole, a first wiring surface and a second wiring surface. The heat sink has a first surface and a second surface. The second wiring surface of the substrate and the second surface of the heat sink are coplanar. The chip is mounted on the substrate and has an active surface and a rear surface. The rear surface of the chip is mounted on the first surface of the heat sink through a thermal interface material layer and the active surface is electrically connected to the first wiring surface of the substrate. The encapsulation is formed on the first wiring surface of the substrate and encapsulates the chip.

Based on the foregoing description, in the semiconductor package of the present invention, the heat sink is embedded in the substrate. The rear surface of the chip contacts to the first surface of the heat sink through the thermal interface material layer so that heat generated from the chip is quickly transmitted to the heat sink. Furthermore, since the second surface of the heat sink is exposed to air, the heat absorbed by the heat sink is dissipated to air. Therefore, a heat dissipation performance of the semiconductor package is increased.

To achieve the objective as mentioned above, the manufacturing method has steps of: (a) preparing a flip chip package and a substrate having an embedded heat sink, a first wiring surface and a second wiring surface; and the embedded heat sink has a first surface and a second surface, wherein the second wiring surface of the substrate and the second surface of the heat sink are coplanar; (b) forming a thermal interface material layer on a rear surface of the flip chip package or the first surface of the embedded heat sink; (c) mounting the flip chip package on the first wiring surface of the substrate to electrically connect to the substrate, wherein the rear surface of the flip chip package is mounted on the first surface of the embedded heat sink through the thermal interface material layer; and (d) forming an encapsulation on the first wiring surface of the substrate to encapsulate the flip chip package.

Based on the foregoing description, in the manufacturing method of the present invention, the substrate having the embedded heat sink is used. The rear surface of the chip contacts to the first surface of the heat sink through the thermal interface material layer so that heat generated from the chip is quickly transmitted to the heat sink. Furthermore, since the second surface of the heat sink is exposed to air, the heat absorbed by the heat sink is dissipated to air. Therefore, a heat dissipation performance of the semiconductor package is increased. In addition, the substrate having an embedded heat sink is previously made, so no complex step is newly added in the manufacturing method of the semiconductor package.

Other objectives, advantages and novel features of the invention will become more apparent from the following detailed description when taken in conjunction with the accompanying drawings.

### BRIEF DESCRIPTION OF THE DRAWINGS

FIG. 1 is a cross-sectional view of a first embodiment of a semiconductor package in accordance with the present invention;

FIG. 2 is a cross-sectional view of a second embodiment of a semiconductor package in accordance with the present invention;

FIG. 3 is a cross-sectional view of the semiconductor package mounted on a printed circuit board (PCB) in accordance with the present invention;

FIGS. 4A to 4F are cross-sectional views of a manufacturing method of the semiconductor package in accordance with the present invention; and

FIG. 5 is a cross-sectional view of a conventional semiconductor package in accordance with the prior art.

### DETAILED DESCRIPTION OF THE PREFERRED EMBODIMENTS

The present invention provides a semiconductor package with an internal heat sink and manufacturing method thereof to increase a heat dissipation performance of the semiconductor package. With embodiments and drawings thereof, the features of the present invention are described in detail as follow.

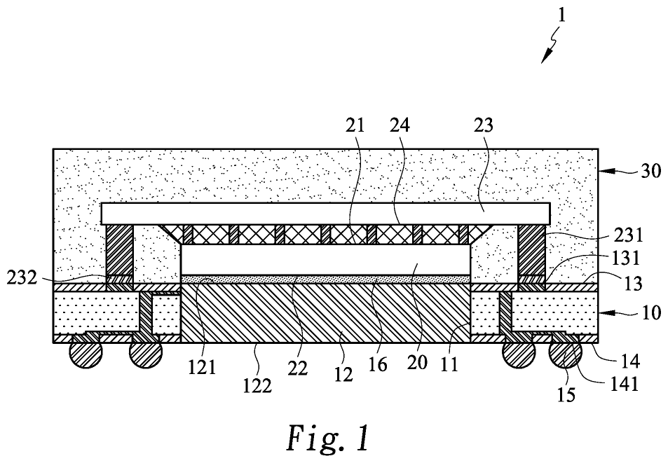

FIG. 1 shows a semiconductor package 1 according to a first embodiment of the present invention. The semiconductor package 1 has a substrate 10, a chip 20 and an encapsulation 30.

The substrate 10 has a through hole 11, a heat sink 12 mounted in the through hole 11, a first wiring surface 13 and a second wiring surface 14. The first wiring surface 13 has a plurality of first outer pads 131 and the second wiring surface 14 has a plurality of second outer pads 141. The heat sink 12 has a first surface 121 and a second surface 122. The second wiring surface 14 of the substrate10 and the second surface 122 of the heat sink 12 are coplanar. In the first embodiment, the substrate 10 further has a plurality of solder bumps 15 respectively mounted on the second outer pads 141 of the second wiring surface14 of the substrate 10.

The chip 20 is mounted on the substrate 10 and has an active surface 21 and a rear surface 22. The rear surface 22 of the chip 20 is mounted on the first surface 121 of the heat sink 12 through a thermal interface material layer 16. The active surface 21 is electrically connected to the first wiring surface 13 of the substrate 10. In the first embodiment, the active surface 21 is electrically connected to the first wiring surface 13 of the substrate 10 through an interposer 23. The interposer 23 has a plurality of metal pillars 231. The active surface 21 of the chip 20 is mounted on the interposer 23 and an underfill 24 is formed between the active surface 21 of the chip 20 and the interposer 23 to constitute a flip chip package. The metal pillars 231 are next to sides of the chip 20 but not covered by the underfill 24. A plurality of solder balls 232 are respectively formed on the metal pillars231 so the metal pillars 231 are respectively soldered to the first outer pads 131 of the first wiring surface 13 of the substrate 10.

The encapsulation 30 is formed on the first wiring surface 13 of the substrate 10 to encapsulate the chip 20. In the first embodiment, the encapsulation 30 further encapsulates the interposer 23, the underfill 24, the metal pillars 231 and the solder balls 232. The encapsulation 30 has a thermal conductivity that is lower than a thermal conductivity of the thermal interface material layer 16, such as silver epoxy or the like.

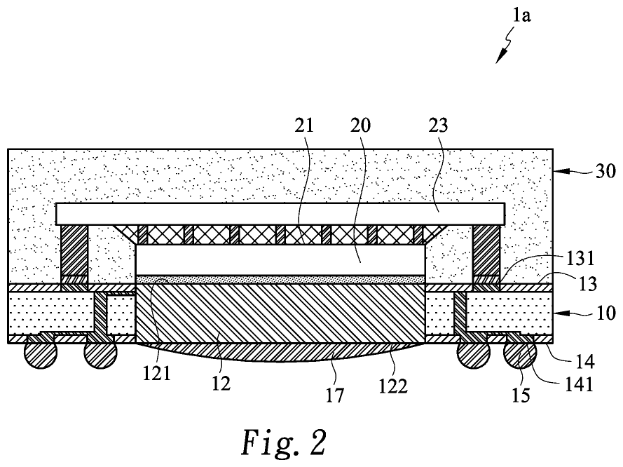

FIG. 2 shows another semiconductor package la according to a second embodiment of the present invention. The semiconductor package la is similar to the semiconductor package 1 in the first embodiment as shown in FIG. 1, but further has a solder layer 17. The solder layer 17 is formed on the second surface 122 of the heat sink 12.

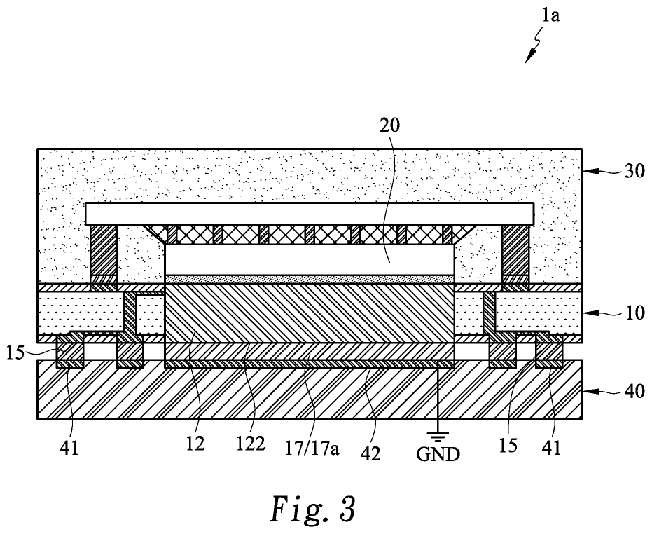

FIG. 3 shows the semiconductor package 1 or la is soldered to a printed circuit board 40. The printed circuit board 40 has a plurality of metal pads 41 and a metal plate 42. In addition, the metal plate 42 may be made of copper, aluminum or the like and may be electrically connected to ground GND. In the first and second embodiments, the solder bumps 14 of the substrate 10 are respectively soldered to the metal pads 41. In the first embodiment, the second surface 122 of the heat sink 12 is soldered to the metal plate 42 by a solder material 17a. In the second embodiment, the solder layer 17 is directly soldered to the metal plate 42.

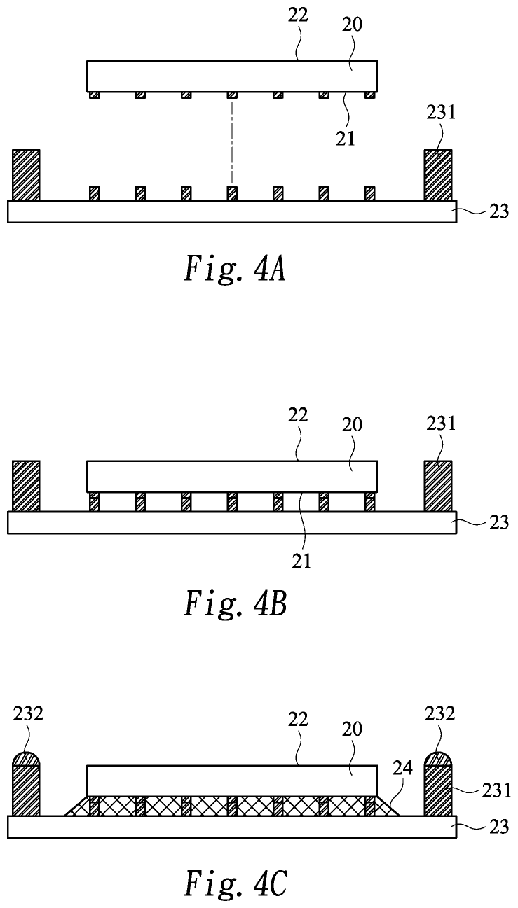

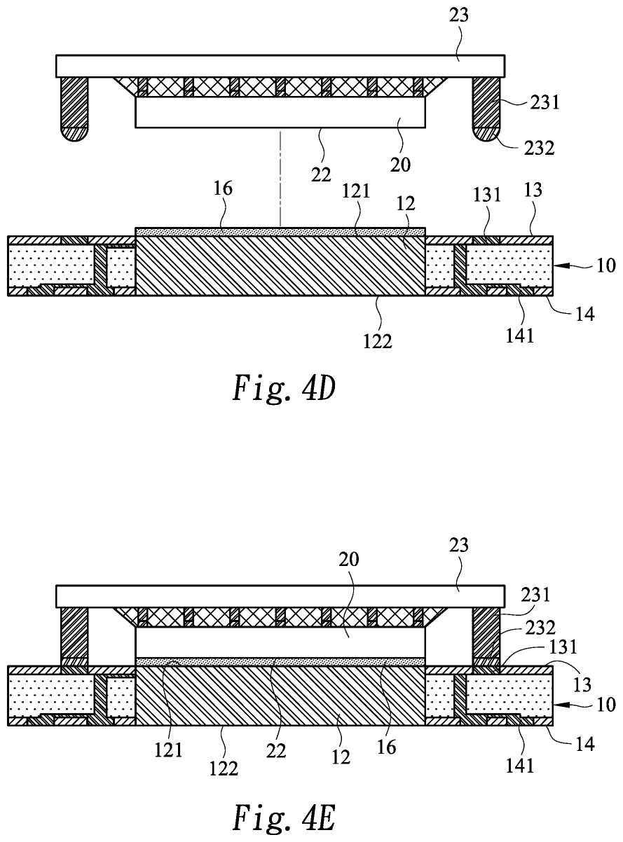

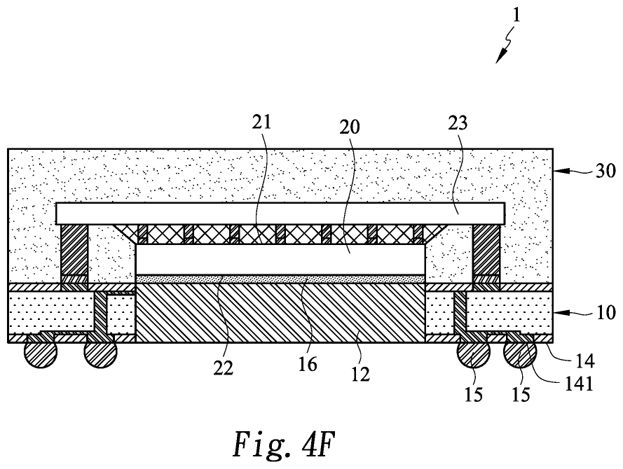

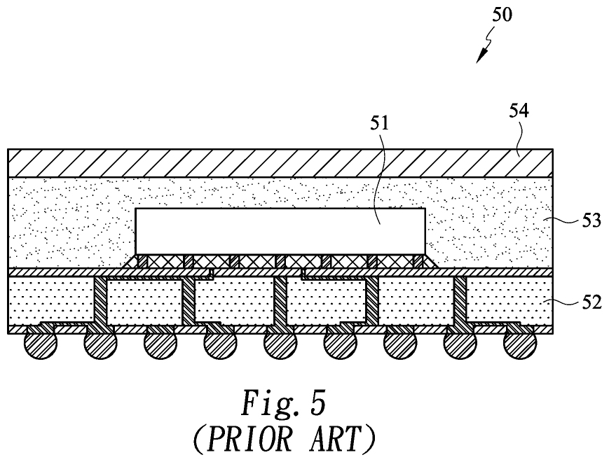

FIGS. 4A to 4F show a manufacturing method of the semiconductor package1 of FIG. 1. The manufacturing method has steps (a) to (d) and an optional step (e).

With reference to FIG. 4D, in the step (a), a flip chip package and a substrate 10 are prepared. The substrate 10 has an embedded heat sink 12, a first wiring surface13 and a second wiring surface14. The embedded heat sink 12 has a first surface 121 and a second surface 122. The second wiring surface 14 of the substrate 10 and the second surface 122 of the heat sink 12 are coplanar. In the embodiment, with further reference to FIGS. 4A to 4C, the step (a) further has steps of: (a1) preparing an interposer 23 and a chip 20, wherein the interposer 23 has a plurality of metal pillars 231; and the chip 20 has an active surface21 and a rear surface 22; (a2) mounting the active face 21 of the chip 20 on the interposer 23 to electrically connected to the interposer 23; (a3) forming an underfill 24 between the active surface 21 of the chip 20 and the interposer 23, wherein the metal pillars 231 and the rear surface 22 of the chip 20 are exposed to air; and (a4) forming a plurality of solder balls 232 on the metal pillars 231 respectively.

With reference to FIG. 4D, in the step (b), a thermal interface material layer 16 is formed on the first surface 121 of the embedded heat sink 12. In the embodiment, the rear surface 22 of the flip chip package is a rear surface 22 of the chip 20. In another embodiment, a thermal interface material layer 16 may be formed on the rear surface 22 of the flip chip package.

With reference to FIG. 4E, in the step (c), the flip chip package is mounted on the first wiring surface 13 of the substrate 10 to electrically connect to the substrate 10. The rear surface 22 of the chip 20 of the flip chip package is mounted on the first surface 121 of the embedded heat sink 12 through the thermal interface material layer 16. At the time, the metal pillars 231 are respectively soldered to a plurality of first outer pads 131 of the first wiring surface 13 of the substrate 10 through the solder balls 232.

With reference to FIG. 4F, in the step (d), an encapsulation 30 is formed on the first wiring surface 13 of the substrate 10 to encapsulate the flip chip package. The encapsulation 30 has a thermal conductivity that is lower than a thermal conductivity of the thermal interface material layer 16.

With reference to FIG. 4F, in the step (e), a plurality of solder bumps 15 are respectively formed on a plurality of second outer pads 141 of the second wiring surface 14 of the substrate 10. At the time, with further reference to FIG. 2, a solder layer 17 may be formed on the second surface 122 of the embedded heat sink 12 to fabricate the semiconductor package la of the second embodiment of the present invention.

With further reference to FIG. 3, the manufacturing method of the present invention further has a step (f). In the step (f), the substrate 10 is formed on a printed circuit board 40. In the embodiment, the printed circuit board 40 has a plurality of metal pads 41 and a metal plate 42. Each of the solder bumps 15 are soldered to the corresponding metal pad 41 and the solder layer 17 is soldered to the metal plate 42. In one embodiment, the metal plate 42 may be electrically connected to ground GND and may be made of copper, aluminum or the like.

Based on the foregoing description, in the manufacturing method of the present invention, the substrate having the embedded heat sink is used. The rear surface of the chip contacts to the first surface of the heat sink through the thermal interface material layer so that heat generated from the chip is quickly transmitted to the heat sink. Furthermore, since the second surface of the heat sink is exposed to air, the heat absorbed by the heat sink is dissipated to air. Therefore, the heat dissipation performance of the semiconductor package is increased. In addition, the substrate having an embedded heat sink is previously made, so no complex step is newly added in the manufacturing method of the semiconductor package.

Even though numerous characteristics and advantages of the present invention have been set forth in the foregoing description, together with the details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A semiconductor package comprising:
a substrate having
a through hole;
a heat sink mounted in the through hole and having a first surface and a second surface;
a first wiring surface; and
a second wiring surface being coplanar with the second surface of the heat sink;
a chip mounted on the substrate and having
an active surface electrically connected to the first wiring surface of the substrate; and
a rear surface mounted on the first surface of the heat sink through a thermal interface material layer; and
an encapsulation formed on the first wiring surface of the substrate and encapsulating the chip.

2. The semiconductor package as claimed in claim 1, further comprising:
an interposer having a plurality of metal pillars respectively mounted on a plurality of first outer pads of the first wiring surface of the substrate, wherein the active surface of the chip is mounted on the interposer; and
an underfill formed between the interposer and the chip.

3. The semiconductor package as claimed in claim 2, further comprising a plurality of solder balls respectively formed on the metal pillars and the metal pillars are respectively soldered to the first outer pads through the solder balls.

4. The semiconductor package as claimed in claim 3, wherein the substrate further comprises a plurality of solder bumps respectively mounted on a plurality of second outer pads of the second wiring surface of the substrate.

5. The semiconductor package as claimed in claim 4, wherein the substrate further comprises a solder layer formed on the second surface of the heat sink.

6. The semiconductor package as claimed in claim 5, further comprising a printed circuit board having:
a plurality of metal pads to which the solder bumps of the substrate are soldered; and
a metal plate to which the solder layer of the heat sink is soldered.

7. The semiconductor package as claimed in claim 6, wherein the metal plate is electrically connected to ground.

8. The semiconductor package as claimed in claim 7, wherein the metal plate is made of copper or aluminum.

9. The semiconductor package as claimed in claim 1, wherein a thermal conductivity of the thermal interface material layer is higher than a thermal conductivity of the encapsulation.

10. The semiconductor package as claimed in claim 9, wherein the thermal interface material layer is silver epoxy.

11. A method for manufacturing semiconductor package comprising steps of:
(a) preparing a flip chip package and a substrate having an embedded heat sink, wherein the substrate has a first wiring surface and a second wiring surface; and the embedded heat sink has a first surface and a second surface, wherein the second wiring surface and the second surface of the heat sink are coplanar;
(b) forming a thermal interface material layer on a rear surface of the flip chip package or the first surface of the embedded heat sink;
(c) mounting the flip chip package on the first wiring surface of the substrate to electrically connect to the substrate, wherein the rear surface of the flip chip package is mounted on the first surface of the embedded heat sink through the thermal interface material layer; and
(d) forming an encapsulation on the first wiring surface of the substrate to encapsulate the flip chip package.

12. The manufacturing method as claimed in claim 11, wherein the step (a) further comprising steps of:
(a1) preparing an interposer and a chip, wherein the interposer has a plurality of metal pillars; and the chip has an active surface and the rear surface;
(a2) mounting the active face of the chip on the interposer to electrically connected to the interposer; and
(a3) forming an underfill between the active surface of the chip and the interposer, wherein the metal pillars and the rear surface of the chip are exposed.

13. The manufacturing method as claimed in claim 12, wherein the step (a) further comprises:
(a4) forming a plurality of solder balls on the metal pillars respectively.

14. The manufacturing method as claimed in claim 13, wherein in the step (c), the metal pillars are respectively soldered to a plurality of first outer pads of the first wiring surface of the substrate.

15. The manufacturing method as claimed in claim 14, further comprising:
(e) Forming a plurality of solder bumps on a plurality of second outer pads of the second wiring surface of the substrate respectively.

16. The manufacturing method as claimed in claim 15, wherein in the step (e), a solder layer is formed on the second surface of the heat sink.

17. The manufacturing method as claimed in claim 16, further comprising:
(f) mounting the substrate on a printed circuit board having a plurality of metal pads and a metal plate, wherein each of the solder bumps are soldered to the corresponding metal pad and the solder layer is soldered to the metal plate.

18. The manufacturing method as claimed in claim 17, wherein the metal plate is electrically connected to ground.

19. The manufacturing method as claimed in claim 18, wherein the metal plate are made of copper or aluminum.

20. The manufacturing method as claimed in claim 11, wherein a thermal conductivity of the thermal interface material layer is higher than that of the encapsulation.
